(19) United States
(12) Patent Application Publication
(10) Pub. No.: US 2022/0020637 A1
(43) Pub. Date: Jan. 20, 2022

(54) METHOD FOR PREPARING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Yachao XU, Hefei (CN)

(21) Appl. No.: 17/408,591

(22) Filed: Aug. 23, 2021

Related U.S. Application Data
(63) Continuation of application No. PCT/CN2021/101628, filed on Jun. 22, 2021.

(30) Foreign Application Priority Data
Jul. 20, 2020 (CN) 202010696959.9

(51) Int. Cl. H01L 21/768; H01L 21/56; H01L 23/31; H01L 23/532

(52) U.S. Cl. CPC H01L 21/76832; H01L 21/76831; H01L 21/76826; H01L 23/53295; H01L 21/56; H01L 23/3171; H01L 23/53266; H01L 21/76837

(57) ABSTRACT

A method for preparing a semiconductor structure and the semiconductor structure are provided. The method for preparing the semiconductor structure comprises: providing a semiconductor substrate and forming a conductive layer on the semiconductor substrate; forming a first protective layer on a surface of the conductive layer; performing a passivation treatment on the first protective layer to enable the first protective layer to form a passivation layer, wherein the passivation layer comprises a multilayer thin film structure and ion concentrations of the multilayer thin film structure are not the same; forming an insulation layer on the passivation layer; and sequentially forming a barrier layer and a second protective layer on the insulation layer.

### CROSS-REFERENCE TO RELATED APPLICATIONS

This is a continuation application of International Patent Application No. PCT/CN2021/101628, filed on Jun. 22, 2021, which claims priority to Chinese patent application No. 202010696959.9, filed on Jul. 20, 2020 and entitled “Method for Preparing Semiconductor Structure and Semiconductor Structure”. The disclosures of International Patent Application No. PCT/CN2021/101628 and Chinese patent application No. 202010696959.9 are incorporated herein by reference in their entireties.

### TECHNICAL FIELD

The present disclosure relates to the technical field of semiconductors, and more particular, to a method for preparing a semiconductor structure and the semiconductor structure.

### BACKGROUND

FIG. 1 representatively illustrates a layered diagram of an existing semiconductor structure. As shown in FIG. 1, the existing semiconductor structure includes a semiconductor substrate 110, a silicon dioxide layer 121 (SiO₂), a silicon nitride layer 122 (SIN) and a polyimide layer 123 (Polyimide). A metal connection layer 111 is formed on the semiconductor substrate 110, and the silicon dioxide layer 121, the silicon nitride layer 122 and the polyimide layer 123 are sequentially formed on the metal connection layer 111 of the semiconductor substrate 110. As a result of integrity of a crystal structure of a silicon dioxide crystal layer, water vapor will permeate into the metal connection layer 111 via the silicon dioxide layer 121 in a certain way to further affect the performance of a semiconductor device. Thus, in a preparation process of the semiconductor, it is relatively high in process requirement on the thickness and the quality of a film which prevents water vapor.

In an existing preparation process, prior to coating the polyimide layer 123, the silicon nitride layer 122 is grown first generally, and permeation of the water vapor is prevented by virtue of high densification of the silicon nitride layer 122.

In addition, as a process for a High Density Plasma (HDP) dielectric layer, a HDP technology is often applied to a back end preparation process of a passivation layer. However, High Density Plasma Chemical Vapor Deposition (HDP-CVD) is a high power deposition process, which is easy to damage a metal conductive layer on a top layer of the metal connection layer 111, such that the reliability of the metal connection layer 111 is reduced. At the same time, in the existing process, an interrupted spare region of the metal conductive layer is not protected by a high densification material and the water vapor still permeates into the metal connection layer 111 via silicon dioxide, which corrodes metal and shortens the service life of the semiconductor device.

### SUMMARY

A main object of the present disclosure is to provide a method for preparing a semiconductor structure capable of sufficiently preventing permeation of water vapor and reducing parasitic capacitance to overcome at least one defect in the related art.

Another main object of the present disclosure is to provide a semiconductor structure to overcome at least one defect in the related art.

In order to achieve the objects, the present disclosure adopts the technical scheme as follows.

According to one aspect of the present disclosure, a method for preparing a semiconductor structure is provided, which includes the following operations.

A semiconductor substrate is provided and a conductive layer is formed on the semiconductor substrate.

A first protective layer is formed on a surface of the conductive layer.

A passivation treatment is performed on the first protective layer to enable the first protective layer to form a passivation layer, and the passivation layer includes a multilayer thin film structure and ion concentrations of the multilayer thin film structure are not the same.

An insulation layer is formed on the passivation layer.

A barrier layer and a second protective layer are sequentially formed on the insulation layer.

According to another aspect of the present disclosure, a semiconductor structure is provided, which includes a semiconductor substrate, a conductive layer, a passivation layer, an insulation layer, a barrier layer and a second protective layer. The conductive layer is arranged on the semiconductor substrate. The passivation layer is formed by a passivation treatment of a first protective layer arranged on a surface of the conductive layer, and the passivation layer includes a multilayer thin film structure and ion concentrations of the multilayer thin film structure are not the same. The insulation layer, the barrier layer and the second protective layer sequentially arranged on the passivation layer.

### BRIEF DESCRIPTION OF THE DRAWINGS

FIG. 1 is a layered diagram of an existing semiconductor structure.

FIG. 2 is a layered diagram of a semiconductor structure shown according to an exemplary implementation.

FIG. 3 is a layered diagram of a semiconductor structure in one operation of a method for preparing a semiconductor structure shown according to an exemplary implementation.

FIG. 4 is a layered diagram of a semiconductor structure in one operation of a method for preparing a semiconductor structure shown according to an exemplary implementation.

FIG. 5 is a layered diagram of a semiconductor structure in one operation of a method for preparing a semiconductor structure shown according to an exemplary implementation.

FIG. 6 is a layered diagram of a semiconductor structure in one operation of a method for preparing a semiconductor structure shown according to an exemplary implementation.

FIG. 7 is an enlarged diagram of a portion A in FIG. 6.

FIG. 8 is a layered diagram of a semiconductor structure in one operation of a method for preparing a semiconductor structure shown according to an exemplary implementation.

FIG. 9 is a layered diagram of a semiconductor structure in one operation of a method for preparing a semiconductor structure shown according to an exemplary implementation.

FIG. 10 is a layered diagram of a semiconductor structure in one operation of a method for preparing a semiconductor structure shown according to an exemplary implementation.

FIG. 11 is a layered diagram of a semiconductor structure in one operation of a method for preparing a semiconductor structure shown according to an exemplary implementation.

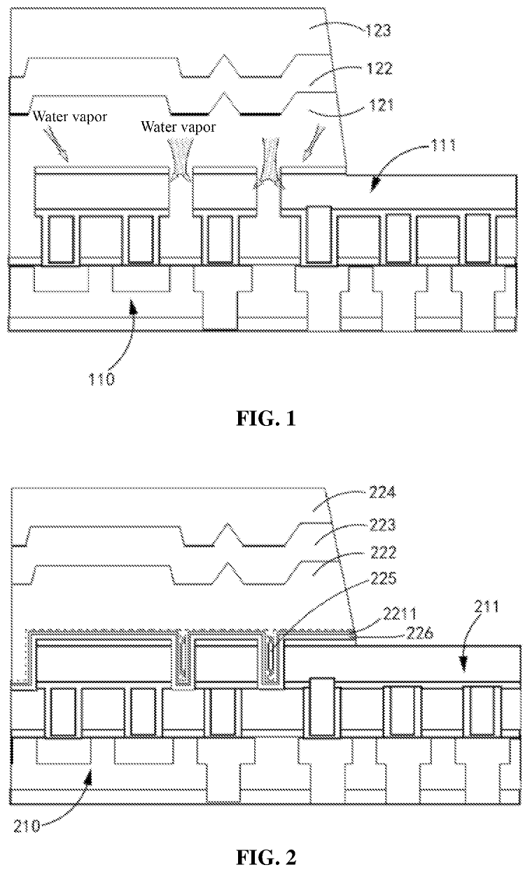

### DETAILED DESCRIPTION

The exemplary implementations will now be described more comprehensively with reference to the accompanying drawings. However, the exemplary implementations may be implemented in various forms and shall not be understood as limitation to the implementations set forth herein. In contrary, these implementations are provided to make the present disclosure more comprehensive and complete, and will comprehensively convey the concept of the exemplary implementations to those skilled in the art. Same reference numerals in the drawings represent same or similar structures, and thus, detailed description thereof will be omitted.

Referring to FIG. 2, which representatively illustrates a layered diagram of the semiconductor structure provided by the present disclosure, and the semiconductor structure is prepared by the method for preparing the semiconductor structure provided by the present disclosure. In the exemplary implementations, the method for preparing the semiconductor structure provided by the present disclosure is described by taking application to preparing a semiconductor structure of a transistor as an example. It may be understood easily by those skilled in the art that in order to apply the related preparation method of the present disclosure to the preparation process of other types of the semiconductor structures, various modifications, additions, substitutions, deletions or other variations are made to the specific implementations. These variations still come within the scope of the principle of the method for preparing the semiconductor structure provided by the present disclosure.

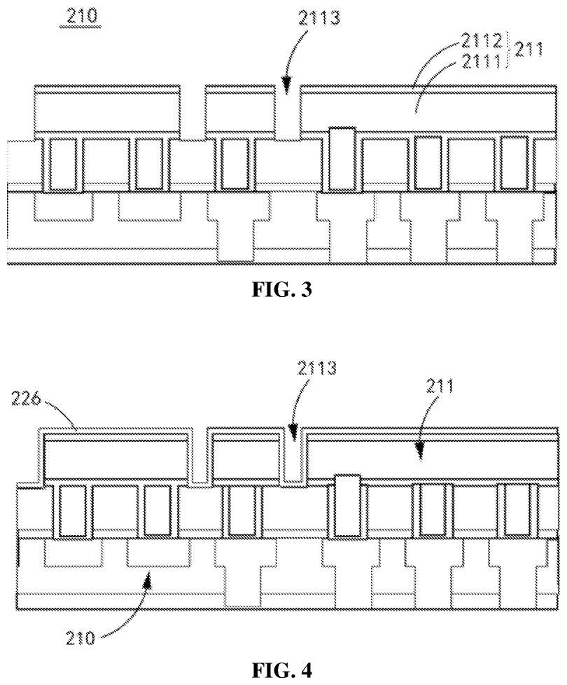

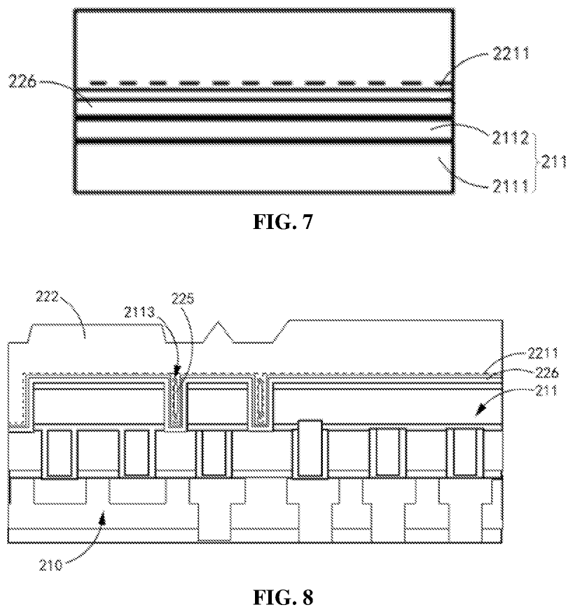

With reference to FIG. 3 to FIG. 11, FIG. 3 to FIG. 6 and FIG. 8 to FIG. 11 representatively illustrate the layered diagram of the semiconductor structure in one operation of the method for preparing the semiconductor structure capable of reflecting the principle of the present disclosure respectively, and FIG. 7 representatively illustrates an enlarged diagram of the portion A in FIG. 6. Detailed description on process, material or sequence of major operations of the method for preparing the semiconductor provided by the present disclosure will be made in combination with the accompanying drawings.

As shown in FIG. 3 to FIG. 11, in the implementation, the method for preparing the semiconductor structure provided by the present disclosure includes the following operations.

A semiconductor substrate 210 is provided and a conductive layer 211 is formed on the semiconductor substrate 210.

A first protective layer 221 (for example, silicon nitride, SIN) is formed on the conductive layer 211.

A passivation treatment is performed on the first protective layer 221 to enable the first protective layer 221 to form a passivation layer 2211, and the passivation layer 2211 includes a multilayer thin film structure and ion concentrations of the multilayer thin film structure are not the same.

An insulation layer 222 (for example, silicon dioxide, SiO₂) is formed on the passivation layer 2211.

A barrier layer 223 and a second protective layer 224 are sequentially formed on the insulation layer 222.

So far, the semiconductor structure is prepared substantially.

By means of the design, according to the method for preparing the semiconductor structure provided by the present disclosure, by forming the first protective layer on the surface of the conductive layer, protection may be provided to the conductive layer 211 by utilizing the first protective layer 221. At the same time, in the present disclosure, the passivation treatment is performed on the first protective layer 221 to enable the first protective layer 221 to form the passivation layer 2211, the passivation layer 2211 includes the multilayer thin film structure, and the ion concentrations of the multilayer thin film structure are not exactly the same, and the ion concentration of at least one layer of the thin film structure of the passivation layer 2211 is higher than that of the first protective layer 221, thereby improving the densification and significantly optimizing the water vapor barrier effect.

It is to be noted that in the operation of performing the passivation treatment on the first protective layer 221, the multilayer thin film structure included in the passivation layer 2211 formed by the first protective layer 221 refers to that the ion concentration in part of regions of the first protective layer 221 changes after the passivation treatment is performed on the first protective layer 221, such that the formed passivation layer 2211 has the plurality of regions with different ion concentrations, i.e., the multilayer thin film structure may be understood as multiple regions with different ion concentrations. From the view of structure, the multilayer thin film structure of the passivation layer 2211 may be, for example, multiple layers stacked sequentially on the surface of the conductive layer 211, i.e., the multiple layered regions with different ion concentrations sequentially stacked, but is not limited thereto.

Specifically, as shown in FIG. 3, FIG. 3 specifically illustrates a layered structure of the semiconductor substrate 210, which may be regarded as a representative example of the semiconductor substrate 210 in the operation of providing the semiconductor substrate 210 in the implementation. The semiconductor substrate 210 is formed with the conductive layer 211 and the conductive layer 211 has an interrupted spare region 2113 in an extension direction. In other implementations, the semiconductor substrate 210 provided in the operation may further be other forms and is not limited to the present implementation.

As shown in FIG. 4, the method for preparing the semiconductor structure provided by the present disclosure may include the operation of forming a dielectric layer 226 on the conductive layer 211 prior to forming the first protective layer 221 on the conductive layer 211. The dielectric layer 226 may be a material with a low dielectric constant, for example, SiCO, which may reduce the parasitic capacitance of the semiconductor device. FIG. 4 specifically illustrates the layered structure after the dielectric layer 226 is formed on the conductive layer 211 of the semiconductor substrate 210. The dielectric layer 226 may preferably be one thin layer structure, and the thin layer structure may be understood that the thin layer structure has a thinner thickness than other layers (for example, the insulation layer 222, the barrier layer 223 or the second protective layer 224) in the back end preparation process. By means of the design of the present disclosure, stress of the first protective layer 221 deposited to the upper layer of the dielectric layer 226 in the subsequent process may be released by utilizing the dielectric layer 226 with high densification and the conductive layer 211 may be protected by utilizing the dielectric layer 226 as well. By means of the design, as the dielectric layer 226 not only has a relatively low dielectric constant but also has better densification, the dielectric layer may further reduce the structural stress while reducing the parasitic capacitance of the semiconductor device. In other implementations, the operation of forming the dielectric layer 226 may be omitted or materials and process operations and the like with similar functions are adopted, which are not limited to the implementation.

The method for preparing the semiconductor structure based on the present disclosure includes the operation of forming the dielectric layer 226. In the implementation, a thickness of the dielectric layer 226 may preferably be 10 nm-100 nm, for example 10 nm, 35 nm, 80 nm, 100 nm and the like. In other implementations, the deposition thickness of the dielectric layer 226 may be smaller than 10 nm or greater than 100 nm, for example, 8 nm, 110 nm and the like and is not limited to the implementation.

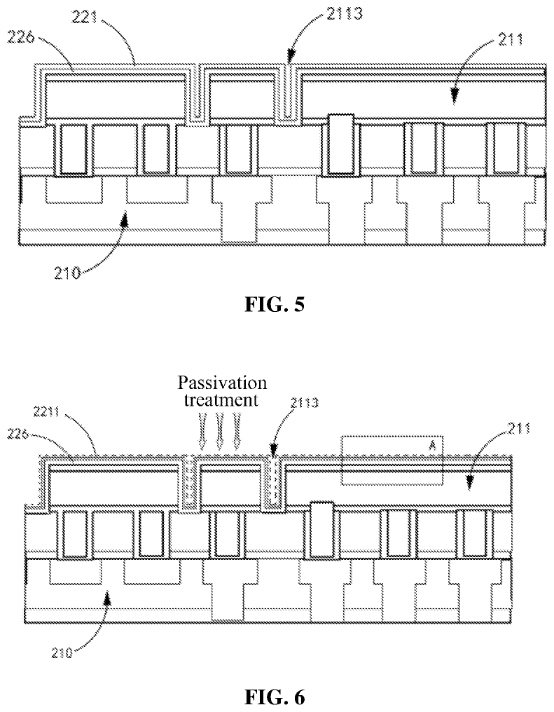

Specifically, as shown in FIG. 5, FIG. 5 specifically illustrates the layered structure after the first protective layer 221 is formed on the dielectric layer 226, which may be regarded as a representative example of the semiconductor structure in the operation of forming the first protective layer 221 in the implementation. In the implementation, based on the operation of forming the dielectric layer 226, the first protective layer 221 is formed on the dielectric layer 226. The first protective layer 221 may preferably be one thin layer structure, and the thin layer structure may be understood that the thin layer structure has a thinner thickness than other layers (for example, the insulation layer 222, the barrier layer 223 or the second protective layer 224) in the back end preparation process. By means of the design of the present disclosure, protection is provided to a side wall of the conductive layer 211 located in the interrupted spare region 2113 by utilizing the first protective layer 221 and the water vapor barrier effect on the conductive layer 211, in particular in the region of the side wall, is optimized as well. In other implementations, when the conductive layer 211 is not formed with the dielectric layer 226, the first protective layer 221 may be formed on the conductive layer 211 or may be formed on other protective structures formed on the conductive layer 211, which is not limited to the implementation.

Based on the operation of forming the first protective layer 221, in the implementation, a thickness of the first protective layer 221 may preferably be 10 nm-100 nm, for example 10 nm, 35 nm, 80 nm, 100 nm and the like. In other implementations, the thickness of the first protective layer 221 may be smaller than 10 nm or greater than 100 nm, for example, 8 nm, 110 nm and the like and is not limited to the implementation.

Specifically, as shown in FIG. 6, FIG. 6 specifically illustrates the layered structure of the first protective layer 221 after the passivation treatment is performed on the first protective layer 221, which may be regarded as a representative example of the semiconductor structure in the operation of performing the passivation treatment on the first protective layer 221 in the implementation. Specifically, as shown in FIG. 6 and FIG. 7, the operation is that the first protective layer 221 is treated by utilizing a passivation treatment process such as a plasma treatment technology after the first protective layer 221 is deposited, such that the first protective layer 221 forms the passivation layer 2211. The passivation layer 2211 has a two-layer thin film structure, including a first layer adjacent to the conductive layer 211 and a second layer located on the surface of the first layer. The densification of the second layer is increased, i.e., an ion concentration of the second layer is raised (for example, the content of nitrogen ions is raised), and the ion concentration of the second layer is higher than that of the first layer. By means of the design of the present disclosure, the plasma treatment is performed on the first protective layer 221 to enable the first protective layer 221 to form the passivation layer 2211, such that the ion concentrations of each layer thin film structure of the passivation layer 2211 with the multilayer thin film structure are not the same, and at least one layer thin film structure of the passivation layer 2211 has a higher ion concentration than the first protective layer 221, thereby optimizing the water vapor barrier effect. In other implementations, the passivation layer 2211 formed after the passivation treatment is performed on the first protective layer 221 may further include a thin film structure of three layers or more, and the ion concentrations of the multilayer thin film structure are not the same.

In other implementations, for the operation of performing the passivation treatment on the first protective layer 221 to form the passivation layer 2211, the passivation treatment may also be other treatment processes, for example, ion implantation or thermal oxidation treatment and the like. According to different process requirements, when a proper passivation treatment process is adopted, the passivation layer 2211 may include the thin film structure of three layers or more, which is not limited to a design that the passivation layer 2211 formed by the passivation treatment in the implementation is substantially divided into two layers. Ion concentrations of various layers of the multilayer thin film structure of the passivation layer 2211 are not the same.

For example, in another implementation, when the passivation treatment is performed on the first protective layer 221 by using the ion implantation process, ions may be injected into a middle region of the first protective layer 221, such that the ion (for example nitrogen ions) concentration of the middle region of the first protective layer 221 is higher than that of other regions, and thus, the formed passivation layer 2211 substantially includes the thin film structure of three layers or more, i.e., at least one layer of the thin film structure in the middle region has a different (for example, higher than) ion concentration from the other regions. In addition, the ions may also be injected into a region adjacent to the conductive layer 211 or a region away from the conductive layer 211 of the first protective layer 221, such that the ion concentrations of the multilayer thin film structure of the formed passivation layer 2211 represent different relationships, which is not limited to the implementation.

It is to be noted that as shown in FIG. 7, the conductive layer 211 in the implementation is described as an example of a conductive structure including an upper metal 2111 and a titanium nitride layer 2112. The titanium nitride layer 2112 is formed on a surface of the upper metal 2111. On this basis, the lowest layer thin film structure of the multilayer thin film structure of the passivation layer 2211 is actually adjacent to the titanium nitride layer 2112.

Based on the operation of performing the plasma treatment on the first protective layer 221, in the implementation, the plasma treatment may include an ammonia gas plasma treatment, i.e., plasma treatment based on ammonia gas (NH₃). In other implementations, plasma treatment processes based on other plasma may also be adopted, for example, low-temperature plasma treatment processes such as a plasma treatment based on argon (Ar) and a plasma treatment based on nitrogen (N₂) or other types of plasma treatment processes may be adopted, which is not limited to the implementation.

Specifically, as shown in FIG. 8, FIG. 8 specifically illustrates the layered structure after the insulation layer 222 is formed on the passivation layer 2211, which may be regarded as a representative example of the semiconductor structure in the operation of forming the insulation layer 222 on the passivation layer 2211 in the implementation. Specifically, the operation is that after the plasma treatment is performed on the first protective layer 221 to enable the first protective layer 221 to form the passivation layer 2211, the insulation layer 222 is formed on the passivation layer 2211. The insulation layer 222 further fills the interrupted spare region 2113 of the conductive layer 211 in addition to a portion formed above the passivation layer 2211.

Based on the operation of forming the insulation layer 222, in the implementation, a forming process of the insulation layer 222 may include a HDP-CVD process. In other implementations, the insulation layer 222 may be formed on the passivation layer 2211 by using other types of depositing processes or other processes, which is not limited to the implementation.

As shown in FIG. 8, based on the operation of forming the insulation layer 222, in the implementation, an air gap 225 is formed in the interrupted spare region 2113 of the conductive layer 211 when the insulation layer 222 is formed. By means of the design, parasitic capacitance of the conductive layer 211 may be reduced, thereby alleviating the defect such as Resistance Control (RC) delay. As a process operation of forming the dielectric layer 226 on the surface of the conductive layer 211 is adopted in the present disclosure, a side surface and a bottom surface of the interrupted spare region 2113 of the conductive layer 211 are covered with the dielectric layer 226. Therefore, compared with an interrupted spare region in an existing process, the interrupted spare region 2113 in the preparation method provided by the present disclosure has a narrower width, that is, a height-width ratio of the interrupted spare region 2113 is increased compared with a corresponding structure in the existing process. Hereby, compared with a design of forming the air gap by multiple processes in the existing preparation method, in the operation of forming the air gap 225 in the present disclosure, the air gap 225 may be formed at one time, such that the process operation is further simplified and the preparation efficiency is improved.

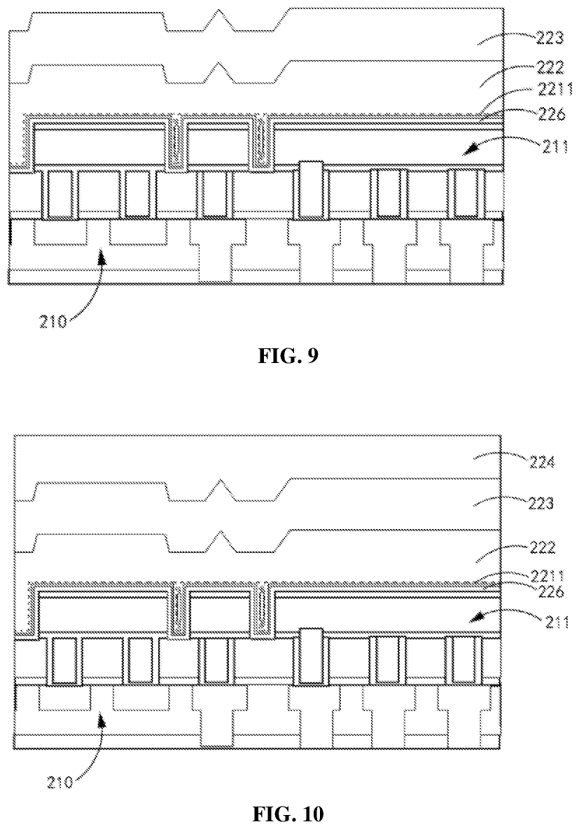

Specifically, as shown in FIG. 9, FIG. 9 specifically illustrates the layered structure after the barrier layer 223 is formed on the insulation layer 222, which may be regarded as a representative example of the semiconductor structure in the operation of forming the barrier layer 223 on the insulation layer 222 in the implementation. Specifically, the operation is that the barrier layer 223 is formed on the insulation layer 222 after the insulation layer 222 is formed, and the barrier layer 223 may be capable of protecting the metal connection layer (conductive layer 211) and preventing water vapor.

Based on the operation of forming the barrier layer 223, in the implementation, the material of the barrier layer 223 may include silicon nitride. In other implementation, the material of the barrier layer 223 may also include other materials such as silicon oxynitride (SiON), which is not limited to the implementation.

Based on the operation of forming the barrier layer 223, in the implementation, the barrier layer 223 may be formed on the insulation layer 222 via a depositing process. In other embodiments, the barrier layer 223 may also be formed on the insulation layer 222 by adopting other processes, which is not limited to the implementation.

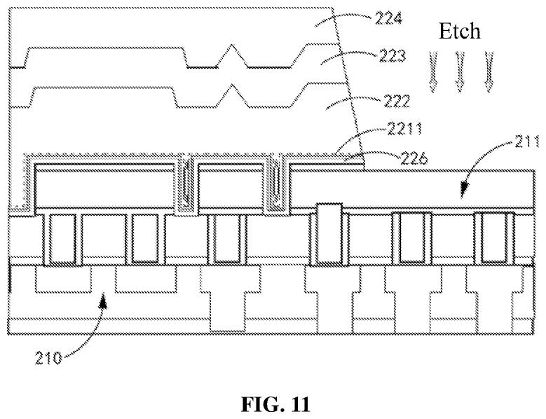

Specifically, as shown in FIG. 10, FIG. 10 specifically illustrates the layered structure after the second protective layer 224 is formed on the barrier layer 223, which may be regarded as a representative example of the semiconductor structure in the operation of sequentially forming the barrier layer 223 and the second protective layer 224 on the insulation layer 222 in the implementation. Specifically, the operation is that the second protective layer 224 is formed on the barrier layer 223 after the barrier layer 223 is formed. The second protective layer 224 may be capable of protecting the semiconductor structure while facilitating the implementation of subsequent process such as etching each film.

Based on the operation of forming the second protective layer 224, in the implementation, a material of the second protective layer 224 may include polyimide. In other implementations, the material of the second protective layer 224 may also include other materials, which is not limited to the implementation.

Based on the operation of forming the second protective layer 224, in the implementation, the second protective layer 224 may be covered on the barrier layer 223 via a spin coating process. In other implementations, the second protective layer 224 may be also formed on the barrier layer 223 by adopting other processes, which is not limited to the implementation.

As described above, as shown in FIG. 10, when the operation of sequentially forming the barrier layer 223 and the second protective layer 224 on the insulation layer 222 is completed, the major process of the semiconductor structure is completed substantially, such that films and related structures are formed on the conductive layer 211 of the semiconductor substrate 210, for example, the dielectric layer 226 including a thin layer, the passivation layer 2211, the insulation layer 222, the air gap 225, the barrier layer 223 and the second protective layer 224.

As shown in FIG. 11, the method for preparing the semiconductor structure provided by the present disclosure may include the operation of etching the film layers. FIG. 11 specifically illustrates the layered structure after the various film layers of the semiconductor structure are etched, and the layered structure of the semiconductor structure illustrated in FIG. 11 is substantially the same with the layered structure of the semiconductor structure illustrated in FIG. 2.

It is to be noted that the method for preparing the semiconductor structure illustrated in the accompanying drawings and described in the description are merely several examples that may adopt the various methods of the principle of the present disclosure. It should be understood clearly that the principle of the present disclosure is by no means limited to any detail or any operation of the method for preparing the semiconductor structure illustrated in the accompanying drawings or described in the description.

Referring to FIG. 2, a layered diagram of the semiconductor structure provided by the present disclosure is representatively illustrated. In the exemplary implementation, the semiconductor structure provided by the present disclosure is described by taking a transistor semiconductor as an example. It may be understood easily by those skilled in the art that, in order to apply the semiconductor structure of the present disclosure to other types of the semiconductors, various modifications, additions, substitutions, deletions or other variations are made to the specific implementations. These variations still come within the scope of the principle of the semiconductor structure provided by the present disclosure.

As shown in FIG. 2, in the implementation, the semiconductor structure provided by the present disclosure includes the semiconductor substrate 210, the conductive layer 211, the passivation layer 2211, the insulation layer 222, the barrier layer 223 and the second protective layer 224. Specifically, the conductive layer 211 is arranged on the semiconductor substrate 210. The passivation layer 2211 may be formed by performing the passivation treatment on the first protective layer 221 arranged on the conductive layer 211. The insulation layer 222, the barrier layer 223 and the second protective layer 224 are sequentially arranged on the passivation layer 2211. The semiconductor structure provided by the present disclosure may be prepared by the method for preparing the semiconductor structure described in detail in the implementation provided by the present disclosure, and in other implementations, the semiconductor structure provided by the present disclosure may also be prepared by other preparation methods, which is not limited to the implementation. By means of the design, the semiconductor structure provided by the present disclosure may provide effective protection to the conductive layer 211 thereof by utilizing the passivation layer 2211, and in particular has the good water vapor barrier effect.

As shown in FIG. 2, in the implementation, the conductive layer has the interrupted spare region 2113, and on this basis, the air gap 225 is arranged in the interrupted spare region 2113.

As shown in FIG. 2, in the implementation, the semiconductor structure provided by the present disclosure may further include the dielectric layer 226. The dielectric layer 226 is arranged between the conductive layer 211 and the passivation layer 2211.

It should be noted that the semiconductor structure illustrated in the accompanying drawings and described in the description merely several examples that may adopt various semiconductor structures of the principle of the present disclosure. It should be understood clearly that the principle of the present disclosure is by no means limited to any detail or any component of the semiconductor structure illustrated in the accompanying drawings or described in the description.

In conclusion, the method for preparing the semiconductor structure provided by the present disclosure may provide protection to the conductive layer by utilizing the first protective layer as the first protective layer is formed on the surface of the conductive layer. At the same time, in the present disclosure, the passivation treatment is performed on the first protective layer to form the passivation layer with the multilayer thin film structure, and the ion concentrations in at least part of regions of the passivation layer are higher than the ion concentration in the first protective layer, thereby significantly optimizing the water vapor barrier effect. Therefore, the semiconductor structure provided by the present disclosure may provide effective protection to the conductive layer thereof, and in particular has the good water vapor barrier effect.

Although the present disclosure has been described with reference to several typical embodiments, it should be understood that the terms used herein are descriptive and illustrative, but not limitative. As the present disclosure may be implemented specifically in various forms without departing from spirit or essence of the present disclosure, it should be understood that the embodiments above are not limited to any above-mentioned details, but should be interpreted broadly in the spirit and scope of the attached claims, and therefore, all variations and modifications falling within the claims or equivalent ranges thereof should be covered by the attached claims.

1. A method for preparing a semiconductor structure, comprising:
providing a semiconductor substrate and forming a conductive layer on the semiconductor substrate;
forming a first protective layer on a surface of the conductive layer;
performing a passivation treatment on the first protective layer to enable the first protective layer to form a passivation layer, wherein the passivation layer comprises a multilayer thin film structure and ion concentrations of the multilayer thin film structure are not the same;
forming an insulation layer on the passivation layer; and
sequentially forming a barrier layer and a second protective layer on the insulation layer.

2. The method for preparing the semiconductor structure of claim 1, wherein the passivation treatment comprises a plasma treatment, an ion implantation treatment or a thermal oxidation treatment.

3. The method for preparing the semiconductor structure of claim 2, wherein the passivation treatment comprises a plasma treatment based on ammonia gas.

4. The method for preparing the semiconductor structure of claim 1, wherein the passivation layer comprises a two-layer thin film structure, the two-layer thin film structure comprises a first layer and a second layer, the first layer is adjacent to the conductive layer, the second layer is located on a surface of the first layer, and an ion concentration of the second layer is higher than that of the first layer.

5. The method for preparing the semiconductor structure of claim 1, wherein the passivation layer comprises a thin film structure of three layers or more, various layers of the thin film structure have different ion concentrations, and at least one layer of the thin film structure has a higher ion concentration than the first protective layer.

6. The method for preparing the semiconductor structure of claim 1, wherein a thickness of the first protective layer is 10 nm-100 nm.

7. The method for preparing the semiconductor structure of claim 1, wherein a forming process of the insulation layer comprises a high density plasma chemical vapor deposition process.

8. The method for preparing the semiconductor structure of claim 1, wherein an air gap is formed in an interrupted spare region of the conductive layer when the insulation layer is formed.

9. The method for preparing the semiconductor structure of claim 1, further comprising:
forming a dielectric layer on the surface of the conductive layer prior to forming the first protective layer.

10. The method for preparing the semiconductor structure of claim 9, wherein a thickness of the dielectric layer is 10 nm-100 nm.

11. The method for preparing the semiconductor structure of claim 9, wherein a material of the dielectric layer comprises SiCO.

12. The method for preparing the semiconductor structure of claim 1, wherein a material of the first protective layer comprises silicon nitride.

13. The method for preparing the semiconductor structure of claim 1, wherein a material of the insulation layer comprises silicon oxide.

14. The method for preparing the semiconductor structure of claim 9, further comprising:
etching the dielectric layer, the passivation layer, the insulation layer, the barrier layer and the second protective layer.

15. The method for preparing the semiconductor structure of claim 1, wherein a material of the barrier layer comprises silicon nitride and silicon oxynitride.

16. The method for preparing the semiconductor structure of claim 1, wherein a material of the second protective layer comprises polyimide.

17. The method for preparing the semiconductor structure of claim 1, wherein the second protective layer is covered on a surface of the barrier layer via a spin coating process.

18. A semiconductor structure, comprising:
a semiconductor substrate;
a conductive layer arranged on the semiconductor substrate;
a passivation layer formed by a passivation treatment of a first protective layer arranged on a surface of the conductive layer, wherein the passivation layer comprises a multilayer thin film structure and ion concentrations of the multilayer thin film structure are not the same; and
an insulation layer, a barrier layer and a second protective layer sequentially arranged on the passivation layer.

19. The semiconductor structure of claim 18, wherein the conductive layer has an interrupted spare region in which an air gap is arranged.

20. The semiconductor structure of claim 18, further comprising:
a dielectric layer arranged between the conductive layer and the passivation layer.
